(19) United States
(12) Patent Application Publication
(10) Pub. No.: US 2004/0206953 A1
(43) Pub. Date: Oct. 21, 2004

(54) Hermetically sealed glass package and method of fabrication

(76) Inventors: Robert Morena, Lindley, NY (US); Mark L. Powley, Campbell, NY (US); Kamjula P. Reddy, Corning, NY (US); Joseph F. Schroeder III, Lindley, NY (US); Alexander Streltsov, Painted Post, NY (US)

Correspondence Address: CORNING INCORPORATED, SP-TI-3-1, CORNING, NY, 14831

(21) Appl. No.: 10/414,653

(22) Filed: Apr. 16, 2003

(51) Int. Cl. H01L 35/24; H01L 51/00; H01L 27/15; H01L 31/12; H01L 33/00

(52) U.S. Cl. 257/40; 257/82

(57) ABSTRACT

A hermetically sealed glass package and method for manufacturing the hermetically sealed glass package are described herein using an OLED display as an example. In one embodiment, the hermetically sealed glass package is manufactured by providing a first substrate plate and a second substrate plate. The second substrate contains at least one transition metal such as iron, copper, vanadium, manganese, cobalt, nickel, chromium, and/or neodymium. A sensitive thin-film device that needs protection is deposited onto the first substrate plate. A laser is then used to heat the doped second substrate plate in a manner that causes a portion of it to swell and form a hermetic seal that connects the first substrate plate to the second substrate plate and also protects the thin film device. The second substrate plate is doped with at least one transition metal such that when the laser interacts with it there is an absorption of light from the laser in the second substrate plate, which leads to the formation of the hermetic seal while avoiding thermal damage to the thin-film device. Another embodiment of the hermetically sealed glass package and a method for manufacturing that hermetically sealed glass package are also described herein.

### CROSS-REFERENCE TO RELATED PATENT APPLICATION

This application is related to a U.S. patent application filed concurrently herewith in the name of Robert M. Morena et al. and entitled “Glass Package that is Hermetically Sealed with a Frit and Method of Fabrication” (Attorney's Docket No. WJT003-0035) which is incorporated by reference herein.

### BACKGROUND OF THE INVENTION

1. Field of the Invention

The present invention relates to hermetically sealed glass packages that are suitable to protect thin film devices that are sensitive to the ambient environment. Some examples of such devices are organic emitting light diode (OLED) displays, sensors, and other optical devices. The present invention is demonstrated using OLED displays as an example.

2. Description of Related Art

OLEDs have been the subject of a considerable amount of research in recent years because of their use and potential use in a wide variety of electroluminescent devices. For instance, a single OLED can be used in a discrete light emitting device or an array of OLEDs can be used in lighting applications or flat-panel display applications (e.g., OLED displays). The OLED displays are known as being very bright and having a good color contrast and wide viewing angle. However, the OLED displays and in particular the electrodes and organic layers located therein are susceptible to degradation resulting from interaction with oxygen and moisture leaking into the OLED display from the ambient environment. It is well known that the lifetime of the OLED display can be significantly increased if the electrodes and organic layers within the OLED display are hermetically sealed from the ambient environment. Unfortunately, in the past it was very difficult to develop a sealing process to hermetically seal the OLED display. Some of the factors that made it difficult to properly seal the OLED display are briefly mentioned below:

The hermetic seal should provide a barrier for oxygen (10⁻³ cc/m²/day) and water (10⁻⁶ g/m²/day).

The size of the hermetic seal should be minimal (e.g., <1 mm) so it does not have an adverse effect on size of the OLED display.

The temperature generated during the sealing process should not damage the materials (e.g., electrodes and organic layers) within the OLED display. For instance, the first pixels of OLEDs, which are located about 2 mm from the seal in the OLED display should not be heated to more than 85° C. during the sealing process.

The gases released during sealing process should not contaminate the materials within the OLED display.

The hermetic seal should enable electrical connections (e.g., thin-film chromium) to enter the OLED display.

Today the most common way for sealing the OLED display is to use different types of epoxies with inorganic fillers and/or organic materials that form the seal after they are cured by ultra-violet light. Although these types of seals usually provide good mechanical strength, they can be very expensive and there are many instances in which they have failed to prevent the diffusion of oxygen and moisture into the OLED display. In fact, these epoxy seals need to use a desiccant to get an acceptable performance. Another potential way for sealing the OLED display is to utilize metal welding or soldering, however, the resulting seal can suffer from the problematical shorting of the electrical leads which enter the OLED display. This sealing process is also very complex since several thin film layers are necessary to get good adhesion. Accordingly, there is a need to address the aforementioned problems and other shortcomings associated with the traditional seals and the traditional ways for sealing the OLED displays. These needs and other needs are satisfied by the hermetic sealing technology of the present invention.

### BRIEF DESCRIPTION OF THE INVENTION

The present invention includes a hermetically sealed OLED display and method for manufacturing the hermetically sealed OLED display. In one embodiment, the hermetically sealed OLED display is manufactured by providing a first substrate plate and a second substrate plate. The second substrate contains at least one transition metal such as iron, copper, vanadium, manganese, cobalt, nickel, chromium and/or neodymium. OLEDs are deposited onto the first substrate plate. A laser is then used to heat the doped second substrate plate in a manner that causes a portion of it to swell and form a hermetic seal that connects the first substrate plate to the second substrate plate and also protects the OLEDs. The second substrate plate is doped with at least one transition metal such that when the laser energy is absorbed there is an increase in temperature in the sealing area. Another embodiment for manufacturing OLED displays is also described herein.

### BRIEF DESCRIPTION OF THE DRAWINGS

A more complete understanding of the present invention may be obtained by reference to the following detailed description when taken in conjunction with the accompanying drawings wherein:

FIGS. 1A and 1B are a top view and a cross-sectional side view illustrating the basic components of a hermetically sealed OLED display in accordance with a first embodiment of the present invention;

FIG. 2 is a flowchart illustrating the steps of a preferred method for manufacturing the hermetically sealed OLED display shown in FIGS. 1A and 1B;

FIGS. 3A and 3B are photographs of partial top views of a substrate plate and sealing glass plate that were at least partially sealed to one another using a 20 watt laser and a 25 watt laser in accordance with the method shown in FIG. 2;

FIG. 4 is a graph that shows the profiles of the swelled region on the free surface of the first embodiment of the doped substrate plate that were made using a 810 nm laser operating at 15 watts, 20 watts and 25 watts;

FIG. 5 is a graph that shows the height variation of the swelled region shown in FIG. 4 for the laser operating at 20 watts;

FIG. 6 is a graph that shows the thermal expansion curves of a substrate plate (glass code 1737 made by Corning Inc.) and two sealing glass plates (composition nos. 4-5) that can be used to make glass packages in accordance with the method shown in FIG. 2;

FIG. 7 is a photograph of 1737 substrate plate that was sealed to sealing glass plate (composition no. 5) in experiment #2;

FIG. 8 is a photograph of 1737 substrate plate that was sealed to sealing glass plate (composition no. 5) in experiment #3;

FIG. 9 is a graph that shows the thermal expansion curves of 1737 and three sealing glass plates (composition nos. 6-8) that can be used to make glass packages in accordance with the method shown in FIG. 2;

FIGS. 10A and 10B are a top view and a cross-sectional side view illustrating the basic components of a hermetically sealed OLED display in accordance with a second embodiment of the present invention;

FIG. 11 is a flowchart illustrating the steps of a preferred method for manufacturing the hermetically sealed OLED display shown in FIGS. 10A and 10B; and

FIG. 12 is a photograph of a top view of a melted fiber which bonded two substrates together using a 25-watt laser beam in accordance with the method shown in FIG. 11.

### DETAILED DESCRIPTION OF THE DRAWINGS

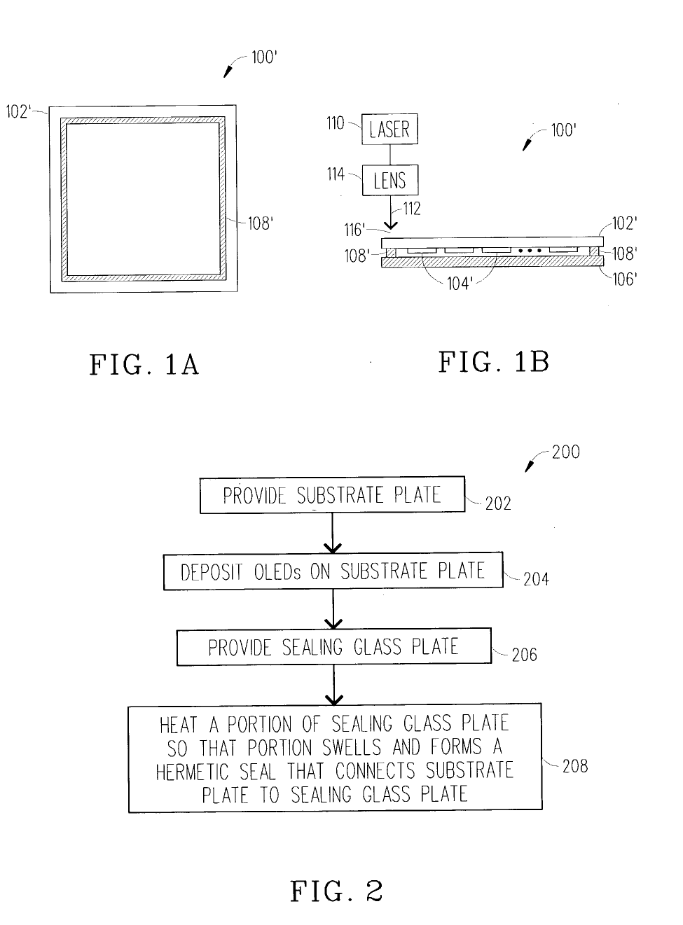

Referring to FIGS. 1-12, there are disclosed in accordance with the present invention two embodiments of hermetically sealed OLED displays 100′ and 100″ and methods 200 and 1100 for manufacturing the OLED displays 100′ and 100″. Although the sealing process of the present invention is described below with respect to the fabrication of hermetically sealed OLED displays 100′ and 100″, it should be understood that the same or similar sealing process can be used in other applications to protect sensitive optical/electronic devices that are disposed between two glass plates. Accordingly, the present invention should not be construed in a limited manner.

Referring to FIGS. 1A and 1B there are a top view and a cross-sectional side view illustrating the basic components of the first embodiment of the hermetically sealed OLED display 100′. The OLED display 100′ includes a multilayer sandwich of a substrate plate 102′ (e.g., glass plate 102′), an array of OLEDs 104′ and a sealing glass plate 106′ that was doped with at least one transition metal including iron, copper, vanadium, manganese, cobalt, nickel, chromium or neodymium (for example). The OLED display 100′ has a hermetic seal 108′ formed from the sealing glass plate 106′, which protects the OLEDs 104′ located between the substrate plate 102′ and the sealing glass plate 106′. The hermetic seal 108′ is typically located just inside the outer edges of the OLED display 100′. And, the OLEDs 104′ are located within the perimeter of the hermetic seal 108′. How the hermetic seal 108′ is formed from the sealing glass plate 106′ and the components such as the laser 110 and lens 114, which are used for forming the hermetic seal 108′ are described in greater detail below with respect to FIGS. 2-9.

Referring to FIG. 2, there is a flowchart illustrating the steps of the preferred method 200 for manufacturing the hermetically sealed OLED display 100′. Beginning at step 202, the substrate plate 102′ is provided so that one can make the OLED display 100′. In the preferred embodiment, the substrate plate 102′ is a transparent glass plate like the one manufactured and sold by Corning Incorporated under the brand names of Code 1737 glass or Eagle 2000™ glass. Alternatively, the substrate plate 102′ can be a transparent glass plate like the ones manufactured and sold by the companies like Asahi Glass Co. (e.g., OA10 glass and OA21 glass), Nippon Electric Glass Co., NHTechno and Samsung Corning Precision Glass Co. (for example).

At step 204, the OLEDs 104′ and other circuitry are deposited onto the substrate plate 102′. The typical OLED 104′ includes an anode electrode, one or more organic layers and a cathode electrode. However, it should be readily appreciated by those skilled in the art that any known OLED 104′ or future OLED 104′ can be used in the OLED display 100′. Again, it should be appreciated that this step can be skipped if an OLED display 100′ is not being made but instead a glass package is being made using the sealing process of the present invention.

At step 206, the sealing glass plate 106′ is provided so that one can make the OLED display 100′. In the preferred embodiment, the sealing glass plate 106′ is made from a borosilicate (multicomponent) glass that is doped with at least one transition metal including iron, copper, vanadium manganese, cobalt, nickel, chromium or neodymium (for example). The compositions of several exemplary sealing glass plates 106′ are provided below with respect to TABLES 1 and 2.

At step 208, a predetermined portion 116′ of the sealing glass plate 106′ is heated in a manner so that portion 116′ of the sealing glass plate 106′ can swell and form the hermetic seal 1081 (see FIG. 1B). The hermetic seal 108′ connects and bonds the substrate plate 102′ to the sealing glass plate 106′. In addition, the hermetic seal 108′ protects the OLEDs 104′ from the ambient environment by preventing oxygen and moisture in the ambient environment from entering into the OLED display 100′. As shown in FIGS. 1A and 1B, the hermetic seal 108′ is typically located just inside the outer edges of the OLED display 100′.

In the preferred embodiment, step 208 is performed by using a laser 110 that emits a laser beam 112 through a lens 114 (optional) and through the substrate plate 102′ so as to heat the predetermined portion 108′ of the doped sealing glass plate 106′ (see FIG. 1B). The substrate plate 102′ does not absorb the laser energy which helps minimize heat dissipation to organic layers in the OLED device. The laser beam 112 is moved such that it effectively heats a portion 116′ of the doped sealing glass plate 106′ and causes that portion 116′ of the sealing glass plate 106′ to swell and form the hermetic seal 108′. The laser 110 has a laser beam 112 with a specific wavelength and the sealing glass plate 106′ is doped with metal transition ions so as to enhance it's absorption property at the specific wavelength of the laser beam 112. This connection between the laser 110 and sealing glass plate 106′ means that when the laser beam 112 is emitted onto the doped sealing glass plate 106′ at point 116′ there is an increase of absorption of the laser beam 112 at that point 116′ which causes the sealing glass plate 106′ to swell and form the hermetic seal 108′. Because of the increase in the absorption of heat energy in the doped sealing glass plate 106′, the laser beam 112 can move relatively fast over the sealing glass plate 106′ and form the hermetic seal 108′. And, by being able to move the laser beam 112 fast this in effect minimizes the undesirable transfer of heat from the forming hermetic seal 108′ to the OLEDs 104′ within the OLED display 100′. Again, the OLEDs 104′ should not be heated to more than 85° C. during the operation of the laser 110.

Described below are several experiments that were conducted by one or more of the inventors. Basically, the inventors have experimented with and used different regimes of the laser 110 to connect and bond different types of substrate plates 102′ to different types of sealing glass plates 106′. The compositions of these exemplary sealing glass plates 106′ are provided in TABLE 1.

TABLE 1

| Compoaition | | | | | | | | |
|---|---|---|---|---|---|---|---|---|
| Mole % | 1* | 2* | 3* | 4* | 5* | 6* | 7* | 8* |
| SiO₂ | 79.8 | 79.5 | 79.2 | 78.6 | 47 | 47 | 47 | 47 |
| Na₂O | 5.3 | 5.3 | 5.3 | 5.2 | 0 | 0 | 0 | 0 |
| Al₂O₃ | 1.2 | 1.1 | 1.1 | 1.1 | 9.0 | 9 | 9 | 9 |
| B₂O₃ | 13.7 | 13.7 | 13.6 | 13.5 | 27 | 27 | 27 | 27 |
| Fe₂O₃ | 0 | 0.4 | 0.8 | 1.6 | 0 | 0 | 0 | 0 |
| PbO | 0 | 0 | 0 | 0 | 7 | 0 | 0 | 0 |
| CuO | 0 | 0 | 0 | 0 | 10 | 17 | 10 | 10 |
| ZnO | 0 | 0 | 0 | 0 | 0 | 0 | 7 | 0 |
| SrO | 0 | 0 | 0 | 0 | 0 | 0 | 0 | 7 |

*These compositions are associated with the exemplary sealing glass plates 106′.

As can be seen in TABLE 1, each of the exemplary sealing glass plates 106′ has a different type and/or concentration of oxides such as Fe₂O₃, PbO, CuO, ZnO, and SrO (for example). It should be noted that some of these elements are not transitional and some of these elements were not added to induce absorption. The sealing glass plates 106′ in these experiments have an enhanced optical absorption in the near-infrared region and in particular at the 810-nm wavelength. The selection of transition-metal dopants is based on the glass absorption at the laser wavelength which in these experiments is 810 nm. The dopants were selected to absorb at the wavelength of the laser beam 112 which in these experiments was 810 nm. And, the substrate plate 102′ can be chosen such that it does not absorb at 810 nm. Because the optical absorption of the sealing glass plate 106′ is enhanced to correspond with the particular wavelength of the laser 110, the laser 110 is able to move relatively fast to heat the doped sealing glass plate 106′ so that it can form the hermetic seal 108′ while at the same time not overheat the OLEDs 104′.

It should be readily appreciated that in addition to the aforementioned compositions listed in TABLE 1, there may be other compositions of substrate plates 102′ and doped sealing glass plate 106′ which exist or which have yet to be developed but could be connected to one another in accordance with the present invention to make a desirable OLED display 100′.

The optical absorption measurements from several experiments along with the physical properties of the exemplary substrate plates 102′ and exemplary doped sealing glass plates 106′ are provided below in TABLE 2.

TABLE 2

| | | | | | | | | | | Eagle |
|---|---|---|---|---|---|---|---|---|---|---|
| Composition | 1* | 2* | 3* | 4* | 5* | 6* | 7* | 8* | 1737 | 2000 |
| Fe₂O₃ or CuO | 0 | 0.4 | 0.8 | 1.6 | 10 | — | — | — | — | — |
| Thickness (mm) | 2.02 | 2.04 | 2.12 | 2.1 | 0.66 | — | — | — | — | — |
| Transmission % | 92.11 | 46.77 | 15.66 | 0.63 | 0.48 | — | — | — | — | — |
| at 800 nm | | | | | | | | | | |
| Absorption | 0.0407 | 0.3725 | 0.8746 | 2.4130 | 8.10 | ‘3 | ‘3 | — | — | — |
| coefficient/mm | | | | | | | | | | |
| % Absorption | 0.41 | 3.66 | 8.37 | 21.44 | 55.51 | — | — | — | — | — |
| in 100 micron | | | | | | | | | | |
| layer** | | | | | | | | | | |
| % Absorption | 0.81 | 7.81 | 16.04 | 38.25 | 80.2 | — | — | — | — | — |
| in 200 micron | | | | | | | | | | |
| layer*** | | | | | | | | | | |
| Thermal | — | — | — | 3.9 | 3.7 | 3.0 | 3.35 | 4.2 | 4.2 | 3.61 |
| Expansion | | | | | | | | | | |
| (ppm/° C.) to | | | | | | | | | | |
| strain point | | | | | | | | | | |
| Annealing | — | — | — | — | — | 482 | 526 | 526 | 721 | 722 |
| Temperature | | | | | | | | | | |
| (° C.) | | | | | | | | | | |
| Strain Point | — | — | — | — | — | 443 | 486 | 488 | 666 | 666 |
| (° C.) | | | | | | | | | | |

*These compositions are associated with the exemplary sealing glass plates 106′.
**The % Absorption in 100 and 200 micron layers were calculated from the equation I/Iₒ = exp(−α1) where α is the absorption coefficient and 1 is the distance.

As can be seen in TABLE 2, the desired degree of laser energy absorption can be achieved by: (1) selecting the particular transition metal(s) to be incorporated within the sealing glass plate 106′ and (2) selecting the concentration or amount of transition metal(s) to be incorporated within the sealing glass plate 106′.

Experiment #1

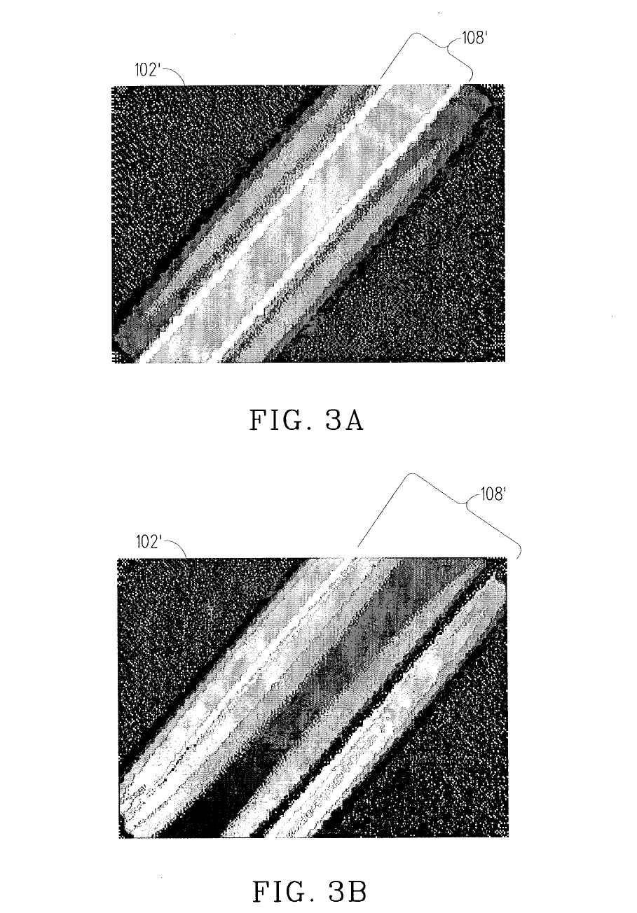

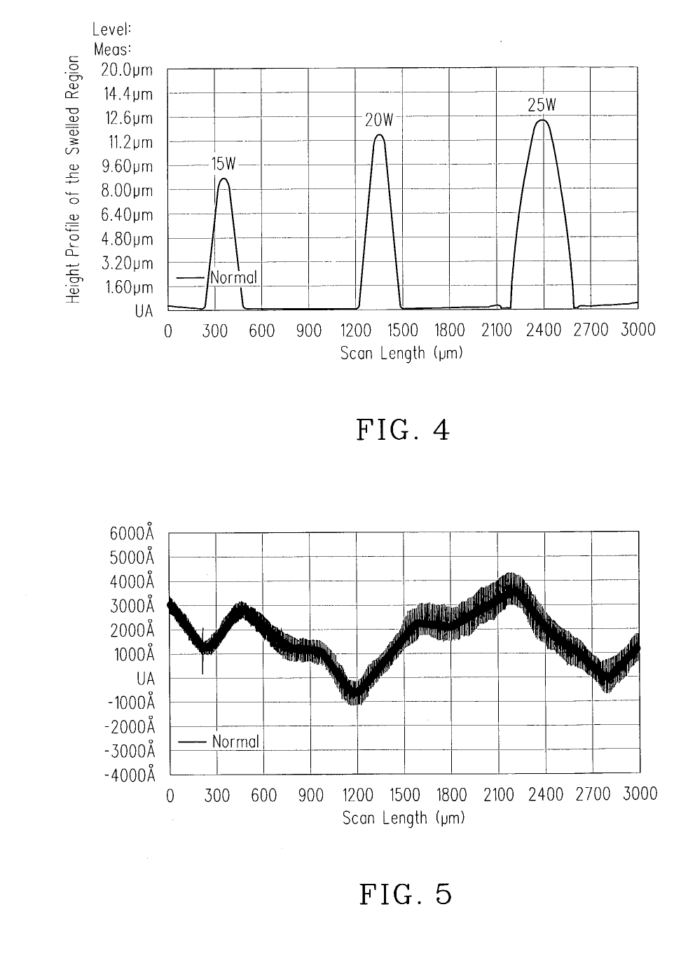

In this experiment, a 25 watt laser 110 was used to focus a 810 nm continuos-wave laser beam 112 through the substrate plate 102′ (e.g., composition no. 9) onto the sealing glass plate 106′ (composition no. 4) (see FIG. 1B). The laser beam 112 moved at a speed of 1 cm/s to form the seal 108′ which connected the substrate plate 102′ to the sealing glass plate 106′. FIGS. 3A and 3B are photographs taken by an optical microscope of partial top views of two plates 102′ and 106′ that were at least partially connected to one another using a 25 watt laser beam 112. As can be seen, very good seals 108′ were obtained when the laser 100 had a power setting of 20 and 25 watts. The seals 108′ where approximately 250 microns wide in FIG. 3A and 260 microns wide in FIG. 3B. The sealing glass plate 106′ swelled and formed a miniscule or ridge during melting which created a gap of approximately 8 microns between the substrate plate 102′ and sealing glass plate 106′. This gap is sufficient to accommodate OLEDs 104′ (not present) which are approximately 2 microns thick. The profiles of the ridges at various laser powers are shown in the graph of FIG. 4. As can be seen, the height of the ridges ranges from approximately 9 μm using a 15 watt laser 110 to approximately 12.5 μm using a 25 watt laser 110. The graph in FIG. 5 shows that the height variation of the ridge made by the 20-watt laser. This ridge is relatively uniform over it's length since its height fluctuates approximately ±250 nm.

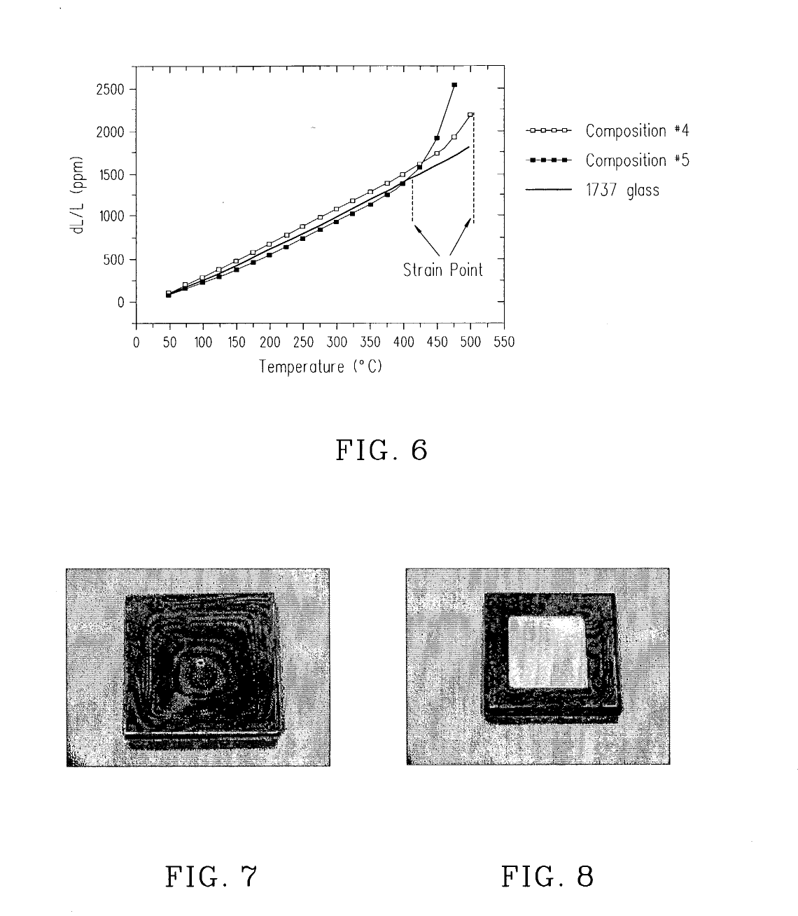

Unfortunately, difficulties were encountered in closing the seal 108′ around the edges of the two aforementioned exemplary glass plates 102′ and 106′ (composition nos. 4 and 9) due to the presence of significant residual stresses. In particular, cracking was observed if the laser beam 112 passed over an already-swelled region in the sealing glass plate 106′ (composition no. 4). Thus, the inventors decided to explore other glass compositions to solve this seal-closing problem. In doing this, the inventors noted that the physical properties (e.g., strain point and thermal expansion) of sealing glass plates 106 and 106′ (composition nos. 4 and 5) indicated that it may be possible to lower the problematical residual stresses. FIG. 6 is a graph that shows the thermal expansion curves of the substrate plate 102′ (composition no. 9) and two sealing glass plates 106′ (composition nos. 4 and 5). As can be seen, the mismatch strain between substrate plate 102′ (composition no. 9) and sealing glass plate 106′ (composition no. 5) which is 80 ppm is significantly lower when compared to the mismatch strain between substrate plate 102′ (composition no. 9) and sealing glass plate 106′ (composition no. 4) which is 360 ppm. As such, when a laser 110 was used to connect substrate plate 102′ (1737 glass substrate ) to sealing glass plate 106′ (composition no. 5) cracks were not present when the seal 108′ crossed over itself at 90°. Moreover, because the sealing glass plate 106′ (composition no. 5) is softer and contains more energy absorbing transition metal(s) than sealing glass plate 106′ (composition no. 4), the laser power required for good sealing was 50% less when compared to the laser power needed to seal the sealing glass plate 106′ (composition no. 4).

Experiment #2

To test the gas leakage through the seal 108′ between two plates 102′ and 106′, a helium-leak test was developed. A 50×50×0.7 mm substrate plate 102′ (1737 glass substrate) with a 3 mm diameter hole at its center was sealed to a 50×50×4 mm sealing glass plate 106′ (composition no. 5) (see photograph in FIG. 7). The sample was sealed using a 810 nm laser 110 with a power of 8.5 W and velocity of 15 mm/s. After sealing the two plates 102′ and 106′, the pressure in the sealed cavity was reduced by connecting a vacuum pump to the hole in the substrate plate 102′. The sealed region was pumped down to a pressure of <50 m-torr and helium gas was sprayed around the outer edge of the seal 108′. The helium gas leak rate through the seal 108′ was measured with a detector. The lowest helium leak rate that can be measured with the apparatus was 1×10⁻⁸ cc/s. The Helium leak rate through the seal 108′ was below the detection limit of the instrument. This is indicative of a very good seal 108′.

Experiment #3

To further test the gas leakage through the seal 108′ in the two plates 102′ and 106′ of experiment #2, a calcium leak test was developed. Using an evaporation technique, a thin film of calcium approximately 31×31×0.0005 mm was deposited on a 50×50×0.7 mm substrate plate 102′ (1737 glass substrate ). This plate was sealed to a 50×50×4 mm sealing glass plate 106′ (composition no. 5) under the same sealing conditions described in experiment #2. To demonstrate hermetic performance, the sealed plates 102′ and 106′ were aged in (85° C./85RH environment(see photograph in FIG. 8). This sample was visually inspected periodically to determine whether there was any change in the appearance of the calcium film. If the calcium film is not protected, it reacts with the moisture in the ambient and becomes transparent in a few hours. There was no change in the appearance of calcium film after aging for 2000 hours in the 85° C./85RH environment. This is indicative of a very good seal 108′.

Experiment #4

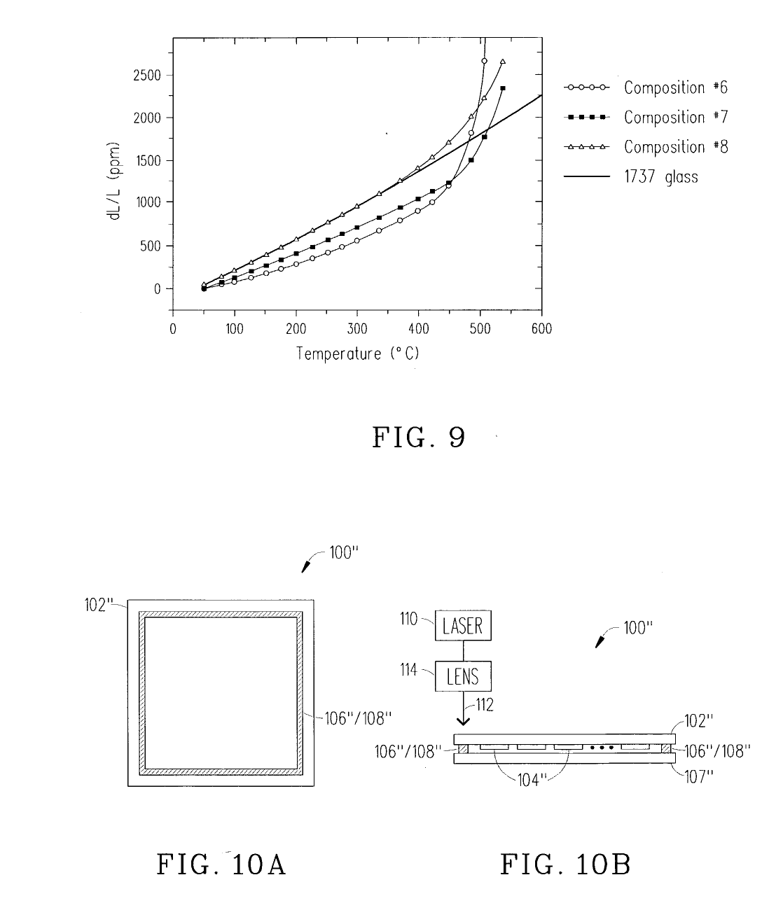

The sealing glass plate 106′ (composition no. 5) contains lead (PbO) in its composition. Glasses containing lead are not generally preferred because of environmental concerns. Therefore, several lead free glass compositions were tested. The compositions of these sealing glass plates 106′ (composition nos. 6-8) were provided in TABLE 1 and their physical properties are given in Table 2. The thermal expansion curves of sealing glass plates 106′ (composition nos. 6-8) and substrate plate 102′ (1737 glass) are shown in FIG. 9. All of these sealing glass plates 106′ showed swelling during heating and excellent bonding to substrate plate 102′ (1737 glass). A sample of sealing glass plate 106′ (composition no. 7) was sealed to substrate glass plate 102′ (1737 glass) for calcium test. The sealing was done with an 8.5 watt laser 110 having a velocity of 15 mm/sec. The sample was aged in 85° C./85RH environment to determine hermetic performance. There was no change in the appearance of the calcium film even though the sample was exposed to this severe moist environment for more than 1800 hours.

Experiment #5

Four calcium test samples were made with substrate plate 102′ (1737 glass) and sealing glass plate 106′ (composition no. 7) using the same sealing conditions described in experiment #4. These samples were subjected to a thermal cycling test between −40° C. to 85° C. The rate of heating during temperature cycling was 2° C./min with 0.5 hour hold at −40° C. and 85° C. (time for each cycle is 3 hours). There was no change in the appearance of the calcium film even after 400 thermal cycles. This indicates that the seal is very robust.

It should be noted that the sealing method of the present invention is very rapid and is also amenable to automation. For example, sealing a 40×40 cm OLED display 100′ can take approximately 2 minutes. And, the doped sealing glass plates 106′ can be manufactured using a float glass process, a slot draw process or a rolling process since the glass surface quality is not that critical for the sealing plate of front-emitting OLED displays 100′.

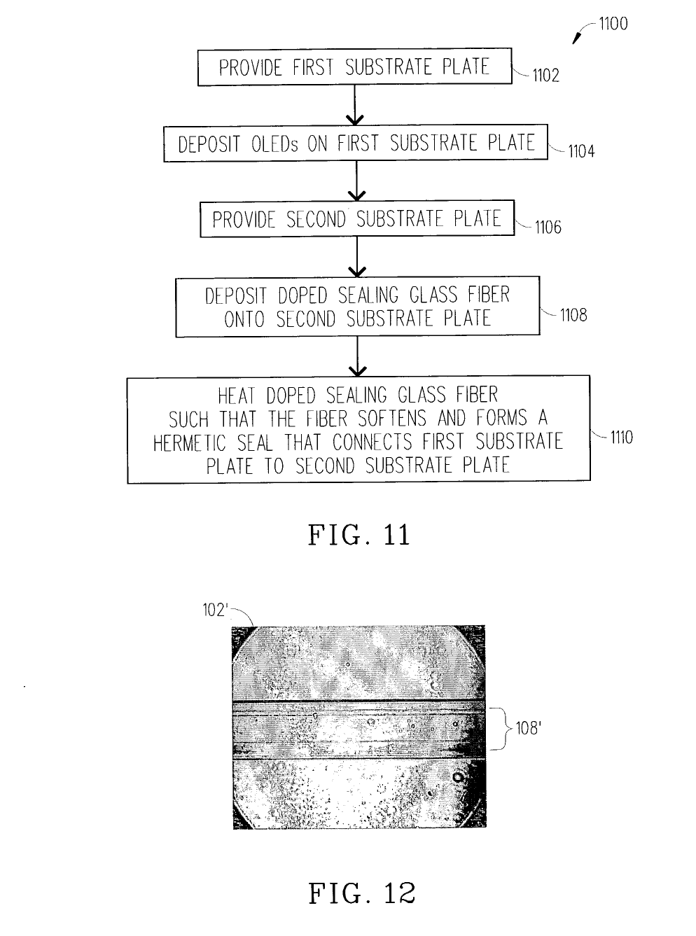

Referring to FIGS. 10A and 10B there are a top view and a cross-sectional side view illustrating the basic components of a second embodiment of the hermetically sealed OLED display 100″. The OLED display 100″ includes a multi-layer sandwich of a first substrate plate 102″ (e.g., glass plate 102″), an array of OLEDs 104″, a sealing glass fiber 106″ that was doped with at least one transition metal including iron, copper, vanadium manganese, cobalt, nickel, chromium or neodymium (for example) and a second substrate plate 107″ (e.g., glass plate 107″). The OLED display 100″ has a hermetic seal 108″ formed from the sealing glass fiber 106″ which protects the OLEDs 104″ located between the first substrate plate 102″ and the second substrate plate 107″. The hermetic seal 108″ is typically located just inside the outer edges of the OLED display 100″. And, the OLEDs 104″ are located within a perimeter of the hermetic seal 108″. How the hermetic seal 108″ is formed from the sealing glass fiber 106″ and the components such as the laser 110 and lens 114 which are used for forming the hermetic seal 108″ are described in greater detail below with respect to the method 1100 and FIGS. 11-12.

Referring to FIG. 11, there is a flowchart illustrating the steps of the preferred method 1100 for manufacturing the hermetically sealed OLED display 100″. Beginning at step 1102, the first substrate plate 102″ is provided so that one can make the OLED display 100″. In the preferred embodiment, the first substrate plate 102″ is a transparent glass plate like the ones manufactured and sold by Corning Incorporated under the brand names of Code 1737 glass or Eagle 2000™ glass. Alternatively, the first substrate plate 102″ can be a transparent glass plate like the ones manufactured and sold by the companies like Asahi Glass Co. (e.g., OA10 glass and OA21 glass), Nippon Electric Glass Co., NHTechno and Samsung Corning Precision Glass Co. (for example).

At step 1104, the OLEDs 104″ and other circuitry are deposited onto the first substrate plate 102″. The typical OLED 104″ includes an anode electrode, one or more organic layers and a cathode electrode. However, it should be readily appreciated by those skilled in the art that any known OLED 104″ or future OLED 104″ can be used in the OLED display 100″. Again, it should be appreciated that this step can be skipped if an OLED display 100″ is not being made but instead a glass package is being made using the sealing process of the present invention.

At step 1106, the second substrate plate 107″ is provided so that one can make the OLED display 100″. In the preferred embodiment, the second substrate plate 107″ is a transparent glass plate like the ones manufactured and sold by Corning Incorporated under the brand names of Code 1737 glass or Eagle 2000™ glass. Alternatively, the second substrate plate 107″ can be a transparent glass plate like the ones manufactured and sold by the companies like Asahi Glass Co. (e.g., OA10 glass and OA21 glass), Nippon Electric Glass Co., NHTechno and Samsung Corning Precision Glass Co. (for example).

At step 1106, the sealing glass fiber 106″ is deposited along the edge of the second substrate plate 107″. In the preferred embodiment, the sealing glass fiber 106″ has a rectangular shape and is made from a silicate glass that is doped with at least one transition metal including iron, copper, vanadium, manganese, coblt, nickel, chromium or neodymium (for example). The compositions of several exemplary sealing glass fibers 106″ are provided above in TABLES 1

At step 1108, the OLEDs 104″ and other circuitry are placed on the first substrate plate 102″ or on the second substrate plate 107″. The typical OLED 104″ includes an anode electrode, one or more organic layers and a cathode electrode. However, it should be readily appreciated by those skilled in the art that any known OLED 104″ or future OLED 104″ can be used in the OLED display 100″.

At step 1110, the sealing glass fiber 106″ is heated by the laser 110 (or other heating mechanism such as an infrared lamp) in a manner so that it can soften and form the hermetic seal 108″ (see FIG. 10B). The hermetic seal 108″ connects and bonds the first substrate plate 102″ to second substrate plate 107″. In addition, the hermetic seal 108″ protects the OLEDs 104″ from the ambient environment by preventing oxygen and moisture in the ambient environment from entering into the OLED display 100″. As shown in FIGS. 10A and 10B, the hermetic seal 108″ is typically located just inside the outer edges of the OLED display 100″.

In the preferred embodiment, step 1110 is performed by using a laser 110 that emits a laser beam 112 through a lens 114 (optional) onto the first substrate plate 102″ so as to heat the sealing glass fiber 106″ (see FIG. 10B). The laser beam 112 is moved such that it effectively heats and softens the sealing glass fiber 106″ so that it can form the hermetic seal 108″. Again, the hermetic seal 108″ connects the first substrate plate 102 to the second substrate plate 107. In particular, the laser 110 outputs a laser beam 112 having a specific wavelength (e.g., 800 nm wavelength) and the sealing glass fiber 106″ is doped with a transition metal (e.g., vanadium, iron, manganese, cobalt, nickel, chromium and/or neodymium) so as to enhance it's absorption property at the specific wavelength of the laser beam 112. This enhancement of the absorption property of the sealing glass fiber 106″ means that when the laser beam 112 is emitted onto the sealing glass fiber 106″ there is an increase of absorption of heat energy from the laser beam 112 into the sealing glass fiber 106″ which causes the sealing glass fiber 106″ to soften and form the hermetic seal 108″. The substrate glass plates 102″ and 107″ (e.g., Code 1737 glass plates 102 and 107) are chosen such that they do not absorb much heat if any from the laser 110. As such, the substrate plates 102 and 107 have a relatively low absorption properties at the specific wavelength of the laser beam 112 which helps to minimize the undesirable transfer of heat from the forming hermetic seal 108″ to the OLEDs 104″ within the OLED display 100″. Again, the OLEDs 104″ should not be heated to more than 85° C. during the sealing process. FIG. 12 is photograph of a top view of two substrate plates 102″ and 107″ (composition nos. 9 or 10) that were bonded together using a 25-watt laser beam 112 that was moved at 1 cm/s velocity and focused to an approximate spot of 0.2 mm-0.3 mm onto the sealing glass fiber 106″ (composition no. 4). The width of the seal 108″ in FIG. 12 is approximately 100 microns.

Following are some of the different advantages and features of the present invention:

The hermetic seal 108′ and 108″ has the following properties:

Good thermal expansion match to glass substrate plates 102′, 102″ and 107′.

Low softening temperature.

Good chemical and water durability.

Good bonding to glass substrate plates 102′, 102″ and 107″.

Seal is dense with very low porosity.

The doped sealing glass plate 106′ can be any type of glass that has the ability to swell. For instance, glasses that have the ability to swell in addition to the ones listed in TABLE 1 include Pyrex™ and Corning Codes 7890, 7521 or 7761. There are other considerations in addition to having a doped sealing glass 106′ and 106″ that can swell which should also be taken into account in order to form a “good” hermetic seal 108′ and 108″. These considerations include having the right match between the CTEs and the viscosities of the sealed glasses. It should be noted that residual stress measurements have indicated that it is preferable to have the CTE of the sealing glass 106′ and 106″ the same as or lower than the CTE of the substrate glass 102′, 102″ and 107″. Other considerations to achieve a “good” hermetic seal 108′ and 108″ include choosing the right conditions such as laser power, focusing and velocity of sealing.

It is important to understand that other types of substrate plates 102″ and 107″ besides the Code 1737 glass plates and EAGLE 2000™ glass plates can be sealed to one another using the sealing process of the present invention. For example, glass plates 102″ and 107″ made by companies such as Asahi Glass Co. (e.g., OA10 glass and OA21 glass), Nippon Electric Glass Co., NHTechno and Samsung Corning Precision Glass Co. can be sealed to one another using the sealing process of the present invention.

The OLED display 100 can be an active OLED display 100 or a passive OLED display 100.

The sealing glass plate and sealing glass fiber of the present invention can be designed to absorb heat in other regions besides the infrared region described above.

In another embodiment, a transparent glass plate that exhibits “swelling” behavior can be coated with a thin layer (e.g., 200-400 nm) of material (e.g., silicon, oxides and nitrides of transitional metals) that strongly absorbs laser light at a chosen wavelength. A substrate glass plate (e.g., Code 1737 glass plate, Eagle 2000™ glass plate) and the coated glass plate are placed together such that the thin layer of material (e.g., silicon,) is located between the two plates. The formation of the hermetic seal can be achieved by irradiating the absorbing interface by moving a laser beam through either the coated glass plate or the substrate glass plate.

The invention is also applicable to other types of optical devices besides OLED displays including field emission displays, plasma displays, inorganic EL displays, and other optical devices where sensitive thin films have to be protected from the environment.

Although several embodiments of the present invention has been illustrated in the accompanying Drawings and described in the foregoing Detailed Description, it should be understood that the invention is not limited to the embodiments disclosed, but is capable of numerous rearrangements, modifications and substitutions without departing from the spirit of the invention as set forth and defined by the following claims.

1. A glass package comprising:
a glass plate; and
a sealing glass plate doped with at least one transition metal, wherein said doped sealing glass plate includes a swelled portion that is a hermetic seal which connects said glass plate to said doped sealing glass plate and also creates a gap between said glass plate and said doped sealing glass plate.

2. The glass package of claim 1, wherein said doped sealing glass plate is made from a multi-component glass doped with at least one transition metal including iron, copper, vanadium, manganese, cobalt, nickel, chromium or neodymium.

3. The glass package of claim 1, wherein said doped sealing glass plate has a softening temperature that is lower than the softening temperature of said glass plate.

4-20. (canceled)

21. An organic light emitting diode display, comprising:
a substrate plate;
at least one organic light emitting diode; and
a sealing glass plate doped with at least one transition metal, wherein said doped sealing glass plate includes a swelled portion that is a hermetic seal which connects said substrate plate to said doped sealing glass plate and also creates a gap to make room for said at least one organic light emitting diode to be located between said substrate plate and said doped sealing glass plate and further protects said at least one organic light emitting diode located between said substrate plate and said doped sealing glass plate.

22. The organic light emitting diode display of claim 21, wherein said doped sealing glass plate is made from a multi-component glass doped with at least one transition metal including iron, copper, vanadium manganese, cobalt, nickel, chromium or neodymium.

23. The organic light emitting diode display of claim 21, wherein said substrate plate is a glass plate.

24. The organic light emitting diode display of claim 21, wherein said doped sealing glass plate has a softening temperature that is lower than a softening temperature of said substrate plate.

25-42. (canceled)

43. The glass package of claim 1, wherein said doped sealing glass plate has an enhanced absorption property within an infrared region.

44. The glass package of claim 1, wherein said doped sealing glass plate has a coefficient of thermal expansion (CTE) that is substantially the same as a CTE of said glass plate.

45. The organic light emitting diode display of claim 1, wherein said doped sealing glass plate has an enhanced absorption property within an infrared region.

46. The organic light emitting diode display of claim 1, wherein said doped sealing glass plate has a coefficient of thermal expansion (CTE) that is substantially the same as a CTE of said substrate plate.

47. A doped glass plate which includes at least one metal and also includes a swelled portion which forms a hermetic seal that connects said doped glass plate to a glass plate and also creates a gap between said doped glass plate and said glass plate.

48. A glass package comprising:
a glass plate; and
a sealing glass plate doped with at least one metal, wherein said doped sealing glass plate includes a swelled portion that is a hermetic seal which connects said glass plate to said doped sealing glass plate and also creates a gap between said glass plate and said doped sealing glass plate.
